(19) United States
(12) Patent Application Publication
(10) Pub. No.: US 2006/0146507 A1
(43) Pub. Date: Jul. 6, 2006

(54) Dual-usage fastener

(75) Inventor: Yung-Sheng Lee, Taipei City (TW)

Correspondence Address: LOWE HAUPTMAN BERNER, LLP, 1700 DIAGONAL ROAD, SUITE 300, ALEXANDRIA, VA, 22314, US

(73) Assignee: TATUNG CO., LTD., Taipei City (TW)

(21) Appl. No.: 11/114,162

(22) Filed: Apr. 26, 2005

(30) Foreign Application Priority Data
Dec. 30, 2004 (TW) 093141393

(51) Int. Cl. H05K 1/14

(52) U.S. Cl. 361/758; 361/804

(57) ABSTRACT

Disclosed is a dual-usage fastener, which includes first support member, which has a body for fastening to a case for computer server, a bearing surface at the top of the body for supporting a first circuit board with a SCSI connector, and a top neck vertically upwardly extending from the bearing surface at the center, and a second support member, which has a body fixedly mounted at the top of the top neck of the first support member, and a bearing surface at the top side of the body for supporting a second circuit board with a S-ATA connector.

### BACKGROUND OF THE INVENTION

1. Field of the Invention

The present invention relates to a fastener for use in a computer server and more particularly, to a dual-usage fastener, which is practical for use in a computer server to support a circuit board for S-ATA hard disk drive as well as a circuit board for SCSI hard disk drive.

2. Description of Related Art

In conventional computer servers, different copper pillars, i.e., 7.865 mm copper pillars and 3.75 mm copper pillars are used to support different circuit boards at different elevations to fit S-ATA hard disk drives or SCSI hard disk drives, i.e., when a computer server with S-ATA hard disk drives or SCSI hard disk drives must be equipped with a circuit board having a S-ATA connector or SCSI connector, and different copper pillars must be matched to support the respective circuit board subject to the elevation of the respective S-ATA hard disk drive or SCSI hard disk drive.

According to conventional techniques, different copper pillars are directly riveted to different server cases to fit different hard disk drives. Therefore, two different types of server cases should be prepared to fit different hard disk drives. This method cannot simplify inventory control, and will greatly increase the cost.

### SUMMARY OF THE INVENTION

The present invention has been accomplished under the circumstances in view. It is therefore the main object of the present invention to provide a dual-usage fastener, which is practical for use in a computer server to support a circuit board for S-ATA hard disk drive as well as a circuit board for SCSI hard disk drive.

To achieve this and other objects of the present invention, the dual-usage fastener comprises a first support member, and a second support member. The first support member comprises a body, a bearing surface at the top of the body for supporting a first circuit board, for example, a circuit board with a SCSI connector, and a top neck vertically upwardly extending from the bearing surface. The top neck has a diameter smaller than the body. The second support member is mounted at the top of the first support member, comprising a body fixedly mounted at the top of the top neck of the first support member, and a bearing surface at the top of the body of the second support member adapted for supporting a second circuit board, for example, a circuit board with a S-ATA connector.

As stated above, the fastener has two bearing surfaces disposed at different elevations for selectively supporting different circuit boards, i.e., a circuit board with a SCSI connector or a circuit board with a S-ATA connector to fit SCSI hard disk drive or S-ATA hard disk drive. Because the fastener fits different circuit boards, the invention saves much installation cost.

The dual-usage fastener further comprises a base fixedly mounted at the bottom side of the body of the first support member for fastening to a server case. The base can be made in any of a variety of shapes, for example, polygonal, circular, or oval shape. The dual-usage fastener further comprises a head mounted at the top of the body of the second support member. The head comprises a neck portion vertically upwardly extending from the bearing surface of the second support member at the center, and a hooked portion mounted at the top of the neck portion for hooking on a second circuit board.

Further, the dual-usage fastener can be fastened to a server case with a rivet, by welding or fusing, or through a screw joint.

### BRIEF DESCRIPTION OF THE DRAWINGS

FIG. 1 is a schematic drawing showing dual-usage fastener used in a computer server according to the present invention.

FIG. 2 is a sectional assembly view showing a first installation example of the present invention.

FIG. 3 is a sectional assembly view showing a second installation example of the present invention.

FIG. 4 illustrates an alternate form of the dual-usage fastener according to the present invention.

### DETAILED DESCRIPTION OF THE PREFERRED EMBODIMENT

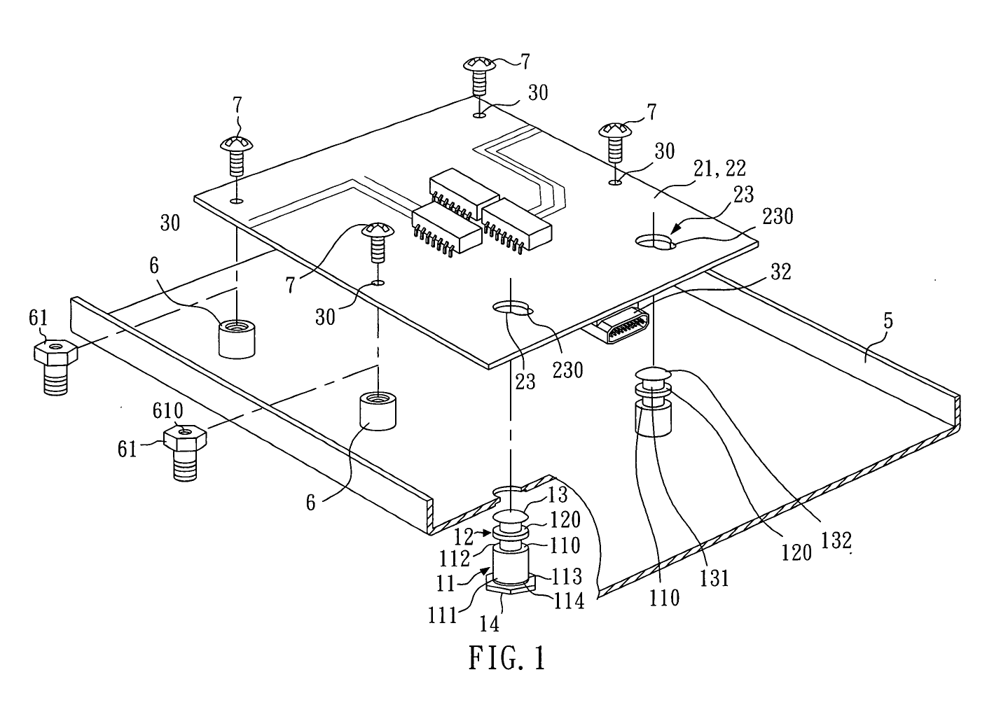

Referring to FIG. 1, a dual-usage fastener 1 is shown comprising a first support member 11, a second support member 12 mounted on the top side of the first support member 11, a head 13 mounted at the top side of the second support member 12, and a base 14 mounted at the bottom side of the first support member 11.

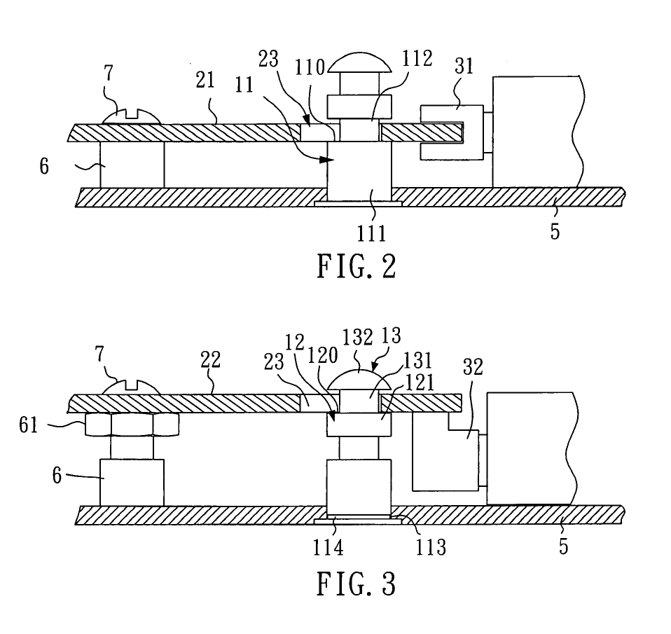

Referring to FIG. 2 and FIG. 1 again, the first support member 11 comprises a body 111. The body 111 has a top bearing surface 110 for supporting a first circuit board 21, which is equipped with a SCSI connector 31. The first support member 11 further comprises a top neck 112 axially upwardly extending from the top bearing surface 110 at the center. The top neck 112 has a diameter smaller than the body 111 and can be engaged into the tail portion 230 of one keyhole 23 of the first circuit board 21.

Referring to FIG. 3 and FIG. 1 again, the second support member 12 comprises a body 121 fixedly mounted at the top side of the top neck 112 of the first support member 11. The diameter of the body 121 of the second support member 12 is greater than the top neck 112 of the first support member 11. The body 121 has a top bearing surface 120 for supporting a second circuit board 22, which is equipped with a S-ATA connector 32.

Referring to FIG. 3 again, the head 13 is mounted at the top side of the top bearing surface 120, comprising a neck portion 131 and a hooked portion 132. According to this embodiment, the neck portion 131 extends vertically upwardly from the top bearing surface 120 of the body 121 of the second support member 12, having a diameter smaller than the body 121 of the second support member 12. The neck portion 131 can be engaged into the tail portion 230 of one keyhole 23 of the second circuit board 22. The hooked portion 132 is mounted at the topside of the neck portion 131 and adapted to hook on the topside of the second circuit board 23.

Referring to FIGS. 1-3 again, the base 14 mounted at the bottom side of the first support member 11, and has a diameter greater than the first support member 11. As illustrated in FIG. 3, the dual-usage pillar 1 is inserted through a countersunk hole at a server case 5, allowing the base 14 to be welded to the countersunk hole at the server case 5 or fixedly fastened thereto by a rivet. Further, a groove 114 extending around the connection area between the root 113 of the first support member 11 and the base 14 for mounting, allowing positive connection of the fastener 1 to the server case 5 without rotation relative to the server case 5.

As indicated above, the dual-usage fastener 1 can support different circuit boards 21, 22 at different heights, which circuit boards 21, 22 are mounted with a SCSI connector 31 or S-ATA connector 32. The server case 5 further comprises a plurality of collar pillars 6. For positively securing the first circuit board 21 in position, screws 7 are respectively inserted through respective through holes 30 at the first circuit board 21 and threaded into the collar pillars 6 to affix the first circuit board 21 in place, keeping the first circuit board 21 firmly supported on the top bearing surface 110 of the first support member 11 of each fastener 1 and the topmost edge of each copper pillar 6 (see FIGS. 1 and 2). For positively securing the second circuit board 21 in position, hexagonal bolts 61 are respectively threaded into the copper pillars 6, and screws 7 are respectively inserted through respective through holes 30 at the second circuit board 21 and threaded into the top center screw hole 610 at each hexagonal bolt 61, keeping the second circuit board 22 firmly supported on the top bearing surface 120 of the second support member 12 of the fastener 1 and the topmost edge of each hexagonal bolt 61 (see FIGS. 1 and 3).

As indicated above, the fastener 1 has two bearing surfaces 110, 120 disposed at different elevations for selectively supporting different circuit boards 21,22 with a SCSI connector 31 or S-ATA connector 32 to fit SCSI hard disk drive or S-ATA hard disk drive. Because the fastener 1 fits different circuit boards 21,22, the invention saves much installation cost.

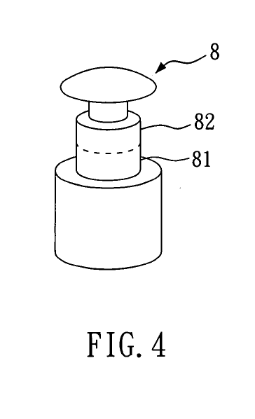

FIG. 4 illustrates an alternate form of the dual-usage fastener. This embodiment is substantially similar to the aforesaid first embodiment with the exception that the support member's top neck 81 and the second support member 82 have the same diameter.

Although the present invention has been explained in relation to its preferred embodiments, it is to be understood that many other possible modifications and variations can be made without departing from the spirit and scope of the invention as hereinafter claimed.

What is claimed is:

1. A dual-usage fastener comprising:
a first support member, said first support member comprising a body, a bearing surface at a top side of said body adapted for supporting a first circuit board, and a top neck vertically upwardly extending from the bearing surface of said first support member at the center, the top neck of said first support member having a diameter smaller than the body of said first support member; and
a second support member mounted at a top side of said first support member, said second support member comprising a body fixedly mounted at a top side of the top neck of said first support member, and a bearing surface at a top side of the body of said second support member adapted for supporting a second circuit board.

2. The dual-usage fastener as claimed in claim 1, further comprising a base fixedly mounted at a bottom side of the body of said first support member for fastening to a device case.

3. The dual-usage fastener as claimed in claim 1, wherein the top neck of said first support member and the body of said second support member have different diameters.

4. The dual-usage fastener as claimed in claim 1, wherein the top neck of said first support member and the body of said second support member have the same diameter.

5. The dual-usage fastener as claimed in claim 1, further comprising a head mounted at a top side of the body of said second support member.

6. The dual-usage fastener as claimed in claim 5, wherein said head comprises a neck portion vertically upwardly extending from the bearing surface of said second support member at the center, and a hooked portion mounted at a top side of said neck portion, said neck portion having a diameter smaller than the body of said second support member.
